(19) United States
(12) Patent Application Publication
(10) Pub. No.: US 2025/0336674 A1
(43) Pub. Date: Oct. 30, 2025

(54) IN SITU DEPOSITION OF FILMSTACKS FOR EUV PATTERNING

(71) Applicant: Applied Materials, Inc., Santa Clara, CA (US)

(72) Inventors: Pramit MANNA, Santa Clara, CA (US); Sudha RATHI, San Jose, CA (US); Rui WANG, Santa Clara, CA (US); Soonil LEE, Santa Clara, CA (US); Karthik JANAKIRAMAN, San Jose, CA (US); Abhijit B. MALLICK, Fremont, CA (US)

(21) Appl. No.: 19/193,029

(22) Filed: Apr. 29, 2025

Related U.S. Application Data
(60) Provisional application No. 63/640,082, filed on Apr. 29, 2024.

(51) Int. Cl. H01L 21/033; G03F 7/16; H01J 37/32; H01L 21/02

(52) U.S. Cl. CPC H01L 21/0332; G03F 7/167; H01J 37/32449; H01L 21/02274; H01J 2237/332

(57) ABSTRACT

In some embodiments, the present disclosure provides methods of processing substrates. A first hardmask gas is introduced to a processing volume of a processing chamber to form an amorphous carbon hardmask film on a substrate disposed in the processing volume. The first hardmask gas includes a carbon containing gas. A second hardmask gas is introduced to the processing volume to form a silicon hardmask film on the amorphous carbon hardmask film. The second hardmask gas includes a silicon containing gas. An underlayer gas mixture is introduced to the processing volume to deposit a resist underlayer on the silicon hardmask film.

### CROSS-REFERENCE TO RELATED APPLICATION

This application claims the benefit of and priority to U.S. Provisional Patent Application No. 63/640,082, filed Apr. 29, 2024, which is incorporated by reference herein in its entirety.

### BACKGROUND

### Field

Embodiments of the present disclosure generally relate to the field of semiconductor processing and, in particular, to methods of forming a resist underlayer for use in extreme ultraviolet (EUV) lithography.

### Description of the Related Art

As geometries of the electronic devices shrink, lithography and patterning for electronic device designs become more challenging. A single lithographic exposure may not be enough to provide sufficient resolution. Typically, for manufacturing integrated circuits (ICs), multiple patterning techniques and additional metal layers are used to increase the feature density. The multiple-patterning techniques and implementation of the additional metal layers complicate the manufacturing technology and are expensive.

The demands for greater integrated circuit densities also impose demands on the process sequences used in the fabrication of integrated circuit components. For example, process sequences that employ conventional lithography techniques for semiconductor device manufacturing primarily employs four operations. These operations include (1) photoresist or “resist” coating; (2) exposure; (3) wet development; and (4) etch. The photoresist coating may include a layer of energy sensitive resist formed over a stack of material layers deposited on a substrate. The energy sensitive resist layer is exposed to an image of a pattern to form a photoresist mask. Thereafter, the mask pattern is transferred to one or more of the material layers of the stack using an etch process. The chemical etchant used in the etch process is selected to have a greater etch selectivity for the material layers of the stack than for the mask of energy sensitive resist. That is, the chemical etchant etches the one or more layers of the material stack at a rate much faster than the energy sensitive resist. The etch selectivity to the one or more material layers of the stack over the resist prevents the energy sensitive resist from being consumed prior to completion of the pattern transfer.

Generally, extreme ultraviolet (EUV) lithography uses EUV wavelengths that are much shorter than the wavelengths of the conventional techniques to scale down the feature sizes on the IC chips. Typically, the EUV lithography uses an EUV wavelength that is about 13.5 nm. The EUV resist, however, is much less resistant to etching than the photoresist used for conventional patterning techniques, which affects selectivity. Currently, the integrity of the EUV resist pattern resulting from etching is very poor compared to that of the conventional photoresists. To use EUV lithography to form features on a substrate, a resist underlayer is typically deposited on a substrate, and then an EUV photoresist is deposited over the resist underlayer.

The lithography processes described above may suffer from several drawbacks. For instance, wet development of resists may produce a pattern having resist line-edge-roughness (LER) due to the in-homogeneity in the resist. This may cause uncertainty in predicting line edges that result following wet development. Additionally, a resolution-(LER)-sensitivity trade off exists, where reducing the LER can reduce the sensitivity of the process. Additionally, as device dimensions shrink, capillary forces due to the small feature size may cause pattern collapsing during wet development and cleaning processes. High aspect ratio patterns are also increasingly being utilized to improve resist roughness performance and provide more etch resistance to allow a wider margin of etch transfer. However, high aspect ratio patterns can also increase the tendency for pattern collapse. Although capillary force may be a main cause of pattern collapse, other factors that can influence pattern collapse include the adhesion force between the photoresist and the underlayer resist film.

Therefore, improvements in EUV lithography are needed.

### SUMMARY

In some embodiments, the present disclosure provides methods of processing substrates. A first hardmask gas is introduced to a processing volume of a processing chamber to form an amorphous carbon hardmask film on a substrate disposed in the processing volume. The first hardmask gas includes a carbon containing gas. A second hardmask gas is introduced to the processing volume to form a silicon hardmask film on the amorphous carbon hardmask film. The second hardmask gas includes a silicon containing gas. An underlayer gas mixture is introduced to the processing volume to deposit a resist underlayer on the silicon hardmask film.

In other embodiments, the present disclosure provides a non-transitory computer readable medium including instructions that, when executed by at least one processor of at least a substrate processing system, cause the at least one processor to perform operations. The operations include introducing a first hardmask gas to a processing volume of a processing chamber to form an amorphous carbon hardmask film on a substrate disposed in the processing volume. The first hardmask gas includes a carbon containing gas. A second hardmask gas is introduced to the processing volume to form a silicon hardmask film on the amorphous carbon hardmask film. The second hardmask gas includes a silicon containing gas. An underlayer gas mixture is introduced to the processing volume to deposit a resist underlayer on the silicon hardmask film.

In other embodiments, the present disclosure provides substrate processing systems. The substrate processing systems include a processing chamber including a processing volume, one or more hardmask gas sources, one or more underlayer gas sources, a substrate support disposed in the processing volume, one or more bias electrodes disposed at least partially in the substrate support, a radiofrequency (RF) source electrically coupled to the one or more bias electrodes, at least one processor, and one or more memories coupled to the at least one processor. The one or more memories store instructions that, when executed by the at least a processor, cause the at least one processor to perform operations. The operations include introducing a first hardmask gas to a processing volume of a processing chamber to form an amorphous carbon hardmask film on a substrate disposed in the processing volume. The first hardmask gas includes a carbon containing gas. A second hardmask gas is introduced to the processing volume to form a silicon hardmask film on the amorphous carbon hardmask film. The second hardmask gas includes a silicon containing gas. An underlayer gas mixture is introduced to the processing volume to deposit a resist underlayer on the silicon hardmask film.

### BRIEF DESCRIPTION OF THE DRAWINGS

So that the manner in which the above recited features of the present disclosure can be understood in detail, a more particular description of the disclosure, briefly summarized above, may be had by reference to embodiments, some of which are illustrated in the appended drawings. It is to be noted, however, that the appended drawings illustrate only exemplary embodiments and are therefore not to be considered limiting of scope, as the disclosure may admit to other equally effective embodiments.

FIG. 1 is a schematic view of a substrate processing system, according to embodiments of the disclosure;

FIG. 2 a schematic, cross-sectional view of a filmstack for use in fabricating an electronic or semiconductor device via EUV lithography, according to embodiments of the disclosure;

FIG. 3 is a process flow diagram depicting a method for producing a filmstack, according to embodiments of the disclosure; and

To facilitate understanding, identical reference numerals have been used, where possible, to designate identical elements that are common to the figures. It is contemplated that elements and features of one embodiment may be beneficially incorporated in other embodiments without further recitation.

### DETAILED DESCRIPTION

Methods of forming a filmstack for use in EUV lithography processes is described herein. In the following description, numerous specific details are set forth in order to provide a thorough understanding of embodiments of the present disclosure. It will be apparent to one skilled in the art that embodiments of the present disclosure may be practiced without these specific details. In other instances, well-known aspects, such as integrated circuit fabrication, are not described in detail in order to not unnecessarily obscure embodiments of the present disclosure. Furthermore, it is to be understood that the various embodiments shown in the Figures are illustrative representations and are not necessarily drawn to scale.

To provide context, conventional EUV patterning techniques using traditional plasma enhanced chemical vapor desorption techniques can result in a roughness of greater than 0.5 nm, which can result in a poor line width roughness (LWR), line pattern collapse (LPR), and/or other lithography related defects.

The present disclosure provides a method for improving adhesion between a carbon hardmask, a silicon hardmask disposed thereon, the resist underlayer disposed thereon, and the EUV photoresist disposed thereon. The methods disclosed herein may be varied to match the surface energy between the layers (e.g., between the carbon hardmask and the silicon hardmask, between the silicon hardmask and the resist underlayer, and between the underlayer and the EUV photoresist) to improve adhesion between the layers (e.g., between the carbon hardmask and the silicon hardmask, between the silicon hardmask and the resist underlayer, and between the underlayer and the EUV photoresist). Without being bound by theory, surface improved adhesion can stabilize the photoresist during etching to improve LER. In one or more embodiments, matching surface energy between layers may be modulated by using different plasma treatments within a processing chamber. The methods disclosed herein can also provide for deposition of a carbon hardmask, silicon hardmask, and the resist underlayer in a single processing volume, thereby increasing interface control without a queue time effect. Moreover, the methods disclosed herein can reduce the roughness of the filmstacks described here, and/or each of the hardmask, the resist underlayer, or the EUV photoresist, thereby positively impacting line width roughness. In some embodiments, the reduction in roughness of the filmstacks does not reduce the LER of the filmstack. Additionally, the methods disclosed herein can provide a higher density carbon and silicon hardmask, thereby increasing etch selectivity of the film stack.

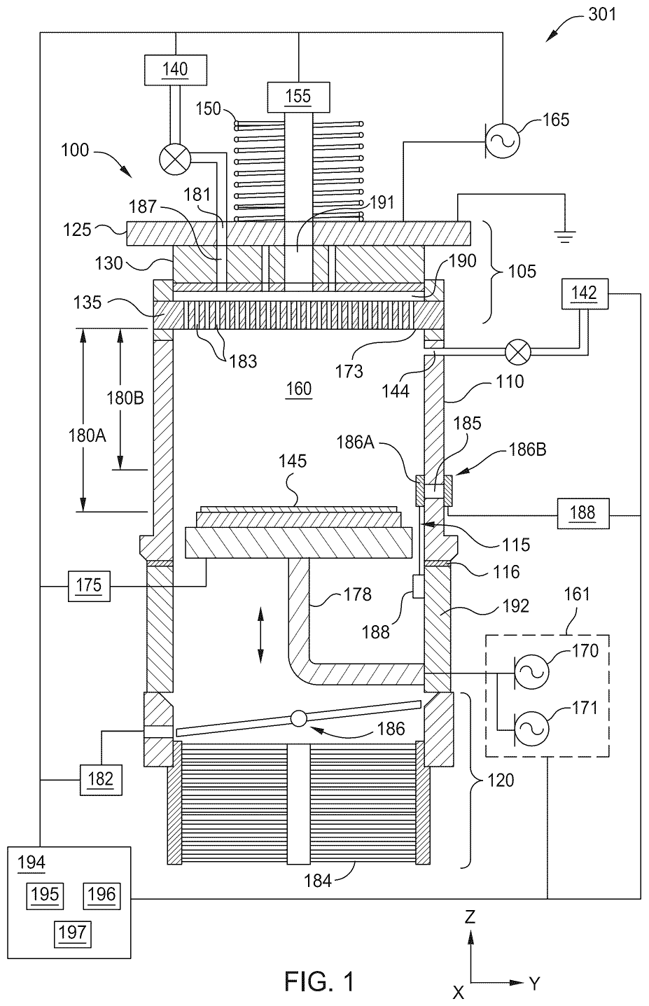

FIG. 1 is a schematic view of a substrate processing system 101, according to one implementation. The substrate processing system 101 includes a processing chamber 100. A side cross-sectional view of the processing chamber 100 is shown in the implementation in FIG. 1.

The processing chamber 100 is configured to conduct a deposition operation on a substrate 145. In one embodiment, which can be combined with other embodiments, the processing chamber 100 is configured to deposit patterning films onto the substrate 145, such as hardmask films, for example, amorphous carbon hardmask films and/or silicon hardmask films.

The processing chamber 100 includes a lid assembly 105, a spacer 110 disposed on a chamber body 192, a substrate support 115 disposed in a processing volume 160, and a variable pressure system 120. The lid assembly 105 includes a lid plate 125 and a heat exchanger 130. In the embodiment shown, which can be combined with other embodiments described herein, the lid assembly 105 also includes a showerhead 135. The lid assembly 105 can include a concave or dome-shaped gas introduction plate in place of the showerhead 135. The showerhead 135 defines a ceiling 173 of the processing volume 160.

One or more first gas sources 140 (one is shown in FIG. 1) are fluidly coupled to the processing volume 160 through the lid plate 125 and a plenum 190 disposed in the lid assembly 105. The one or more first gas sources 140 introduce processing gases for forming films on the substrate 145 supported on the substrate support 115. The processing gases flow into the plenum 190, through the showerhead 135, and into the processing volume 160. The one or more first gas sources 140 are configured to introduce processing gases. The processing gases can include carbon-containing gases (such as hydrocarbon gases), hydrogen-containing gases, silicon-containing gases and/or helium. The present disclosure contemplates that other gases may be used, e.g., borane, diborane, alkyl boranes, any derivatives thereof, and/or any isomers thereof. In one example, which can be combined with other examples, the processing gases include one or more of acetylene (C₂H₂) (which can be referred to as ethyne), propene (C₃H₆), methane (CH₄), butene (C₄H₈), 1,3-dimethyladamantane, bicyclo[2.2.1]hepta-2,5-diene (2,5-norbornadiene), adamantine (C₁₀H₁₆), norbornene (C₇H₁₀), any derivatives thereof, and/or any isomers thereof. In another example, which can be combined with other examples, the processing gases include one or more of silane, disilane, tetrasilane, trisilane, tri silylamine, alkyl silane, any derivatives thereof, and/or any isomers thereof. The processing gases can include one or more dilution gases, one or more carrier gases, etchant gases, and/or one or more purge gases. In one example, which can be combined with other examples, the processing gases include one or more of helium, argon, xenon, neon, nitrogen (N₂), hydrogen (H₂), chlorine (Cl₂), carbon tetrafluoride (CF₄), oxygen, ammonia, nitrous oxide, and/or nitrogen trifluoride (NF₃).

In one embodiment, which can be combined with other embodiments, the one or more first gas sources 140 are configured to introduce any of the above described gases, such as acetylene (C₂H₂) and helium (He), into the processing volume 160.

The one or more first gas sources 140 introduce processing gases through one or more channels formed in the lid assembly 105 (such as channels 181, 187 formed in the lid plate 125 and the heat exchanger 130) and into the plenum 190. The one or more channels 181, 187 formed in the lid assembly 105 direct processing gases from the one or more first gas sources 140, through channels 183 formed in the showerhead 135, and into the processing volume 160. In one embodiment, which can be combined with other embodiments, one or more second gas sources 142 (one is shown in FIG. 1) are fluidly coupled to the processing volume 160 through an inlet 144 disposed through a gas ring with nozzles attached to the spacer 110, or through a chamber side wall.

The one or more second gas sources 142 are configured to optionally introduce one or more processing gases, such as any of the above described process gases. In one embodiment, which can be combined with other embodiments, the one or more second gas sources 142 are configured to introduce acetylene (C₂H₂) and helium (He) into the processing volume 160. In one embodiment, which can be combined with other embodiments, the one or more second gas sources 142 are configured to introduce silane and helium (He) into the processing volume 160. In one embodiment, which can be combined with other embodiments, a total flow rate of processing gases into the processing volume 160—including the flow rates from the one or more first gas sources 140 and the flow rates from the one or more second gas sources 142 (if used)—is about 100 sccm to about 2 slm. The flow of processing gases into the processing volume 160 using the one or more second gas sources 142 is uniformly distributed in the processing volume 160. In one example, which can be combined with other examples, a plurality of inlets 144 may be radially distributed about the spacer 110 or about the chamber sidewall. In such an example, gas flow to each of the inlets 144 may be separately controlled to further facilitate gas uniformity within the processing volume 160.

A dual-frequency radiofrequency (RF) power source 161 is electrically coupled to one or more bias electrodes that are disposed at least partially in the substrate support 115 using a facilities cable 178. The dual-frequency radiofrequency (RF) power source 161 is utilized during the deposition of films, such as a hardmask or underlayer. The dual-frequency RF power source 161 includes a first RF power source 170 and a second RF power source 171 that are each electrically coupled to the one or more bias electrodes 205B. The first RF power source 170 is configured to supply a first RF power to the one or more bias electrodes 205B, and the second RF power source 171 is configured to supply a second RF power simultaneously with the first RF power. The second RF power is less than the first RF power.

The lid assembly 105 (such as the lid plate 125) is coupled to a third RF power source 165. The third RF power source 165 facilitates maintenance or generation of plasma, such as a plasma generated from a cleaning gas. The third RF power source 165 is configured to supply a third RF power to the lid assembly 105, such as when cleaning the upper portion of processing volume 160, such as the showerhead 135, but may also be used during deposition alone or with combination of the dual-frequency radiofrequency (RF) power source 161 for plasma generation. Without being bound by theory, it is believed that the plasma in an upper portion of the processing volume 160 near the showerhead 135 can be of less density and hence the quality of the deposition gas (e.g., ions) in the upper portion can be weak. Using the dual-frequency RF power source 161 and the operational parameters described herein facilitates enhanced deposition, reduced film compressive stress, and maintained film modulus. As an example, the first RF power is used to facilitate generating reactive species and providing ion densities for film deposition, and the second RF power is used to facilitate enhanced ion bombardment for stress reduction.

The first RF power supplied by the first RF power source 170 has a first frequency within a range of 11 MHz to 15 MHz. In one embodiment, which can be combined with other embodiments, the first frequency is 13 MHz or 15 MHz. The second RF power supplied by the second RF power source 171 has a second frequency within a range of 1.8 MHz to 2.2 MHz. In one embodiment, which can be combined with other embodiments, the second frequency is about 2 MHz. The present disclosure contemplates that the first RF power source 170 and the second RF power source 171 can be integrated into a mixed frequency RF power source for the dual-frequency RF power source 161 that is configured to simultaneously supply the first RF power and the second RF power. Dual frequency power, alone or in combination with sub-atmospheric pressure, is believed to further beneficially affect surface energy of films, facilitating improved LER. The lid assembly 105 (such as the lid plate 125) is grounded in the implementation shown in FIG. 1. The present disclosure contemplates that the showerhead 135 can be grounded. The present disclosure contemplates that other components surrounding the processing volume 160 (such as the spacer 110) can also be grounded. The present disclosure contemplates that the chamber body 192 can also be grounded.

The dual-frequency RF power source 161 facilitates maintaining modulus for deposited films (deposited on the substrate 145) while reducing compressive stress of the deposited films relative to other films. Without being bound by theory, the dual-frequency RF power source 161 provides higher ion bombardment which can relax bonding between atoms of the deposited films to reduce compressive stress. The dual-frequency RF power source 161 facilitates the maintained modulus while facilitating enhanced implantation of species (e.g., H, Si, I) into deposited film, increased ionization, and increased deposition rates for the film.

In the implementation shown in FIG. 1, the film on the substrate 145 is deposited to a thickness of 3,000 Angstroms (Å) or greater, such as 5,000 Angstroms or greater. It is contemplated that aspects of the present disclosure can be used in implementations where the film is deposited to a thickness of less than 3,000 Angstroms. The film deposited on the substrate 145 is amorphous carbon hardmask film that may subsequently be used as a hardmask during etching operations. For example, a second film of a silicon hardmask may subsequently be deposited on the substrate 145 after the amorphous carbon hardmask film within the same processing volume 160.

One or more of the dual-frequency RF power source 161 and/or the third RF power source 165 are used to create and/or maintain a plasma in the processing volume 160 while the one or more processing gases are supplied to the processing volume 160 using the one or more first gas sources 140 and/or the one or more second gas sources 142. In one embodiment, which can be combined with other embodiments, the dual-frequency RF power source 161 is used during a deposition operation to deposit film on the substrate 145, and the third RF power source 165 is used during a cleaning operation to remove contaminants or film from interior surfaces of the processing chamber 100.

In the deposition operation, which may be used to deposit either of the first hardmask (i.e., the amorphous carbon hardmask) or the second hardmask (i.e., the silicon hardmask), the dual-frequency RF power source 161 simultaneously supplies the first RF power and the second RF power to the one or more bias electrodes 205B of the substrate support 115. The first RF power is within a first power range of 10 W to about 1000 W, and the second RF power is within a second power range of 10 W to about 1000 W. The first RF power includes a first RF frequency, and the second RF power includes a second RF frequency that is less than the first RF frequency. The first RF frequency is within a range of 11 MHz to 15 MHz, such as 13 MHz to 14 MHz, and the second RF frequency is within a range of 1.8 MHz to 2.2 MHz, such as 1.95 MHz to 2.05 MHz. In one embodiment, which can be combined with other embodiments, the first RF frequency is 13 MHz or 14 MHz, and the second RF frequency is 2.0 MHz. In one or more embodiments, the first RF power and the second RF power, and the ratio between them are dependent on which of the first hardmask and second hardmask is being deposited.

During the deposition operation, the third RF power source 165 may optionally provide a third RF power within a third power range of 10 W to about 20 kW. However, it is also contemplated that the third power soured 165 may not be used during deposition (e.g., may be used only in cleaning), or may not omitted all together. The first RF power, the second RF power, and the third RF power (if the third RF power is used) facilitate ionization of the one or more processing gases, and the ions of the one or more processing gases bombard onto the substrate 145 to deposit the films on the substrate 145. In one embodiment, which can be combined with other embodiments, the one or more processing gases include acetylene (C₂H₂), silane, and/or helium (He), depending upon the composition of the film deposited.

The substrate support 115 is coupled to an actuator 175 (e.g., a lift actuator) that provides movement thereof along the Z direction. The substrate support 115 is coupled to the facilities cable 178 that is flexible, which allows vertical movement of the substrate support 115 while maintaining couplings with the dual-frequency power source 161 as well as other power and fluid couplings. The spacer 110 is disposed on the chamber body 192. A height of the spacer 110 allows movement of the substrate support 115 vertically within the processing volume 160. The height of the spacer 110 is about 0.5 inches to about 20 inches, such as about 6 inches to about 18 inches, such as about 6 inches to about 12 inches. In one embodiment, which can be combined with other embodiments, the substrate support 115 is movable from a first distance 180A to a second distance 180B relative to the ceiling 173 defined by the showerhead 135. In one embodiment, which can be combined with other embodiments, the second distance 180B is about ⅔ of the first distance 180A. A difference between the first distance 180A and the second distance 180B is about 5 inches to about 6 inches. From the position shown in FIG. 1, the substrate support 115 is movable by about 5 inches to about 6 inches relative to a lower surface of the showerhead 135. In one embodiment, which can be combined with other embodiments, the substrate support 115 is fixed at one of the first distance 180A and the second distance 180B.

During the deposition operation, the processing volume 160 and/or the substrate 145 is maintained at a deposition temperature and a deposition pressure. The deposition temperature is within a range of −50 degrees Celsius to 600 degrees Celsius, such as −40 degrees Celsius to 100 degrees Celsius. In one embodiment, which can be combined with other embodiments, the deposition temperature is within a range of −40 degrees Celsius to 40 degrees Celsius, such as within a range of −20 degrees Celsius to 20 degrees Celsius, such as within a range of −5 degrees Celsius to 20 degrees Celsius within a range of 8 degrees Celsius to 12 degrees Celsius. The deposition pressure is sub-atmospheric. The deposition pressure can be about 0.1 mTorr to 2 Torr, e.g., such about 1 mTorr to about 1 Torr, such as about 3 mTorr to about 50 mTorr, such as about 3 mTorr to about 5 mTorr. During the deposition operation the substrate support 115 can be disposed at the second distance 180B from the lower surface of the showerhead 135, and the second distance is within a range of 3.5 inches to 4.5 inches, such as 4.0 inches.

The variable pressure system 120 includes a first pump 182 and a second pump 184. The first pump 182 is a roughing pump that may be used during a cleaning operation and/or substrate transfer operation. A roughing pump is generally configured for moving higher volumetric flow rates and/or operating a relatively higher (though still sub-atmospheric) pressure. In one example, which can be combined with other examples, the first pump 182 maintains a pressure within the processing chamber less than 50 mTorr during a cleaning operation. In one example, which can be combined with other examples, the first pump 182 maintains a pressure within the processing chamber of about 0.5 mTorr to about 10 Torr. Utilization of a roughing pump during cleaning operations facilitates relatively higher pressures and/or volumetric flow of cleaning gas (as compared to a deposition operation). The relatively higher pressure and/or volumetric flow during the cleaning operation facilitates improved cleaning of interior chamber surfaces.

The second pump 184 may be a turbo pump and/or a cryogenic pump. The second pump 184 is utilized during a deposition operation. The second pump 184 is generally configured to operate a relatively lower volumetric flow rate and/or pressure. The second pump 184 is configured to maintain the processing volume 160 of the processing chamber at a pressure of less than about 50 mTorr, such as about 1 mTorr to about 2 Torr. The reduced pressure of the processing volume 160 maintained during deposition facilitates deposition of a film having reduced compressive stress and/or increased sp² to sp³ conversion, when depositing carbon-based hardmasks. Thus, processing chamber 100 is configured to utilize both relatively lower pressure to facilitate improved deposition and relatively higher pressure to facilitate improved cleaning.

A valve 186 is used to control the conductance path to one or both of the first pump 182 and the second pump 184. The valve 186 also provides symmetrical pumping from the processing volume 160.

The processing chamber 100 also includes a substrate transfer port 185. The substrate transfer port 185 is selectively sealed by an interior door 186A and an exterior door 186B. Each of the doors 186A and 186B are coupled to actuators 188 (e.g., a door actuator). The doors 186A and 186B facilitate vacuum sealing of the processing volume 160. The doors 186A and 186B also provide symmetrical RF application and/or plasma symmetry within the processing volume 160. In one example, at least the interior door 186A is formed of a material that facilitates conductance of RF power, such as stainless steel, aluminum, or alloys thereof. Seals 116, such as O-rings, disposed at the interface of the spacer 110 and the chamber body 192 may further seal the processing volume 160.

The lid assembly 105 is optionally coupled to a coil 150. The coil 150 used (with or without the third RF power source 165) can produce an inductively coupled plasma to excite a processing gas and/or a cleaning gas.

The channels 181, 187, a central conduit 191, and the channels 183 can be oriented vertically (e.g., parallel to the Z-axis) and/or can be oriented at an angle (such as an oblique angle) relative to the X-Y plane.

The coils 150 can be used in place of or in addition to the third RF power source 165 during the cleaning operation and/or deposition operation. The present disclosure contemplates that the flat coils 150 can be omitted, and the cleaning gases can be ionized into a plasma in situ using the third RF power source 165.

The substrate processing system 101 includes a controller 194 to control the operations of the substrate processing system 101. The controller 194 is coupled to the one or more first gas sources 140, the one or more second gas sources 142, one or more clean gas sources 155, the actuator 175, the first pump 182, the dual-frequency RF power source 161, the third RF power source 165, and/or the actuators 188 to control the operations thereof. The controller 194 includes a central processing unit (CPU) 195 (a processor), a memory 196 containing instructions, and support circuits 197 for the CPU 195. The controller 194 controls the substrate processing system 101 directly, or via other computers and/or controllers (not shown) coupled to the processing chamber 100. The controller 194 is of any form of a general-purpose computer processor that is used in an industrial setting for controlling various chambers and equipment, and sub-processors thereon or therein.

The memory 196 (a non-transitory computer readable medium) is one or more of a readily available memory such as random access memory (RAM), read only memory (ROM), floppy disk, hard disk, flash drive, or any other form of digital storage, local or remote. The support circuits 197 are coupled to the CPU 195 for supporting the CPU 195 (a processor). The support circuits 197 include cache, power supplies, clock circuits, input/output circuitry and subsystems, and the like.

Substrate processing parameters and operations are stored in the memory 196 as a software routine that is executed or invoked to turn the controller 194 into a specific purpose controller to control the operations of the substrate processing system 101. The parameters stored in the memory 196 can include, for example, the first RF frequency, the second RF frequency, the first power range, the second power range, the frequency ratio range, the second distance 180B, the deposition temperature, the deposition pressure, and gas flow rates. The controller 194 is configured to conduct any of the methods and operations described herein. The instructions stored in the memory 196, when executed by the processor 195, can produce method 300, as described below.

The instructions in the memory 196 of the controller 194 can include one or more machine learning algorithms and/or one or more artificial intelligence algorithms that can be executed in addition to the operations described herein. As an example, a machine learning algorithm or artificial intelligence algorithm executed by the controller 194 can optimize and alter the parameters stored in the memory 196 based on measurements taken during or after operations, such as the deposition operation and/or the cleaning operation. The optimized parameters can include, for example, the first RF frequency, the second RF frequency, the first power range, the second power range, the frequency ratio range, the second distance 180B, the deposition temperature, and/or the deposition pressure. As an example, a machine learning algorithm or artificial intelligence algorithm stored in the memory 196 and executed by the processor 195 can use measurements of film modulus and film compressive stress to optimize the first RF frequency and the second RF frequency of the dual-frequency RF power source 161.

The spacer 110 includes a height that is about 0.5 inches to about 20 inches, such as about 0.5 inches to about 3 inches, such as about 10 inches to about 20 inches, such as about 14 inches to about 16 inches. The spacer 110 provides part of a volume of the processing volume 160. The height of the processing volume 160 provides benefits. One benefit includes a reduction in film stress which decreases stress induced bow in the substrate 145 being processed therein. The height of the processing volume 160 affects plasma density distribution from top to bottom of the processing volume 160. Methods provided herein facilitate maintaining plasma density in the lower portion of the processing volume 160 suitable for film deposition on substrate 145 disposed on the substrate support 115 by using the dual-frequency RF power source 161.

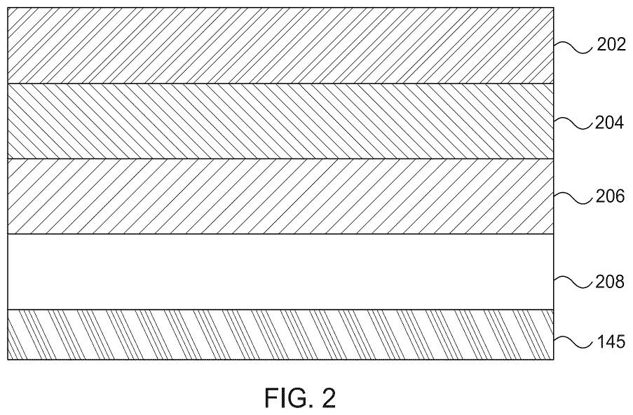

FIG. 2 is a schematic, cross-sectional view of a filmstack 200 for use in fabricating an electronic or semiconductor device, according to certain embodiments of the present disclosure. In an embodiment, the filmstack 200 comprises a photoresist, such as an EUV photoresist 202 disposed on a resist underlayer 204 and a substrate 145. In certain embodiments, the filmstack 200 also includes a silicon hardmask 206 disposed between the resist underlayer 204 and a carbon hardmask 208, e.g., an amorphous carbon hardmask. The carbon hardmask 208 is disposed over the substrate 145. In some embodiments, the resist underlayer 204 may be disposed directly on the substrate 145. In other embodiments, one or more other interlayers, e.g., silicon hardmask 206 and/or carbon hardmask 208, may be disposed between the resist underlayer 204 and the substrate 145.

In some embodiments, the EUV photoresist 202 may include a EUV lithographic positive or negative photoresist. In some embodiments, the carbon hardmask 208 includes a carbon hardmask, which may be formed from a hydrocarbon such as acetylene, propylene, ethylene, and/or a long chain alkane, e.g., C₁-C₂₀ hydrocarbon. In some embodiments, the silicon hardmask 206 includes a silicon carbide hardmask, silicon nitride hardmask, silicon oxide nitride hardmask, amorphous silicon hardmask, silicon oxide hardmask, or other material that is etch selective to the underlying substrate 108.

In one example, which may be combined with other examples, the carbon hardmask 208, the silicon hardmask 206, and the resist underlayer 204 are deposited in the same chamber, or different chambers. When deposited in the same chamber, the carbon hardmask 208, the silicon hardmask 206, and the resist underlayer 204 may be deposited using the same or different plasma sources, such as a capacitively coupled plasma (CCP) or an inductively coupled plasma (ICP) to facilitate different film properties among the carbon hardmask 208, the silicon hardmask 206, and the resist underlayer 204. For example, the carbon hardmask 208, the silicon hardmask 206, and the resist underlayer 204 may each be deposited using an ICP plasma. In another example, the carbon hardmask 208 and the silicon hardmask 206 may be deposited using a CCP plasma, while the resist under layer 204 may be deposited using ICP. Likewise, regardless of plasma source selection, the carbon hardmask 208, the silicon hardmask 206, and the resist underlayer 204 may be deposited using the same or different operational parameters to facilitate desired film qualities. For example, the carbon hardmask 208 and the silicon hardmask 206 may be deposited using a relatively low bias level to promote reduced film stress, while the resist underlay 204 may be deposited using relatively higher bias to promote increased smoothness facilitating improved lithographic processes.

In one example, an ICP plasma source may be used to generate a plasma for deposition of the carbon hardmask 208, the silicon hardmask 206, and the resist underlayer 204, while a separate bias power may be applied to the substrate support to facilitate deposition on a substrate. In such an example, the ICP power source may supply 500-3000 watts of power, while the bias source may be biased with 750-1250 watts of power, during deposition of the carbon hardmask 208 and the silicon hardmask 206. The chamber is maintained at a pressure of about 100 mTorr to about 400 mTorr, such as 100 mTorr to 300 mTorr, such as 100 mTorr to 200 mTorr, although other pressures are contemplated.

During deposition of the underlayer 204, the bias power is reduced, facilitating reduced surface roughness. For example, a bias power of 250 watts to 750 watts is applied, while utilizing a source power of 500 watts to 3000 watts. The chamber is maintained at a pressure of less than 100 mTorr, such as less than 80 mTorr, such as less than 60 mTorr, such as less than 40 mTorr, such as less than 20 mTorr, such as less than 10 mTorr.

In addition, it is contemplated that the underlay 204 has a greater hydrogen content, and is less diamond-like (e.g., lower sp3 hybridization) than the carbon hardmask 208. It is contemplated that variations in processing conditions, such as pressure, bias and/or source power, and precursor selection can contribute to these differences. For example, during deposition of the underlay 204, a carbon-based precursor having a relatively higher atomic ratio or percentage of hydrogen may be used, while during deposition of the carbon hardmask 208, a carbon precursor having a relatively lower atomic ratio or percentage of hydrogen may be used.

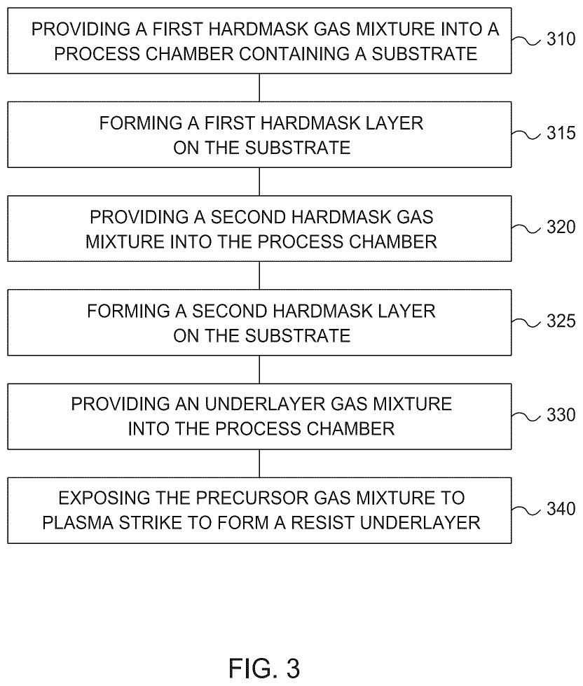

FIG. 3 is a process flow diagram depicting a method 300 for producing a filmstack 200, according to certain embodiments described herein. In one embodiment, the method 300 may be used to deposit the filmstack 200 on the substrate 145 depicted in FIG. 2.

At operation 310, a first processing gas, e.g., a hardmask gas, is provided into a processing region of a process chamber. The first hardmask gas may include at least one hydrocarbon source and/or carbon-containing source. The first hardmask gas may further include an inert gas, a dilution gas, a nitrogen-containing gas, or combinations thereof. In one or more embodiments, the first processing gas is provided at a flow rate of about 50 sccm to about 1200 sccm, such as about 100 sccm to about 1000 sccm.

The hydrocarbon compound has a general formula CxHy, where x has a range of about 1 and 20 and y has a range of about 1 and 20. For example, the hydrocarbon compound can include one or more of acetylene (C₂H₂) (which can be referred to as ethyne), propene (C₃H₆), methane (CH₄), butene (C₄H₈), 1,3-dimethyladamantane, bicyclo[2.2.1]hepta-2,5-diene (2,5-norbornadiene), adamantine (C₁₀H₁₆), norbornene (C₇H₁₀), any derivatives thereof, and/or any isomers thereof.

Suitable dilution, treatment, and or inert gases such as helium (He), argon (Ar), xenon, nitrogen (N₂), N₂O, oxygen (O₂), SiF₄, NF₃, B₂H₆, and SiH₄ or combinations thereof, among others, may be added to the process gas, e.g., the first hardmask gas. Alternatively, dilution gases may not be used during the deposition.

At operation, 315, a first hardmask is formed by exposing the substrate to the first hardmask gas, while maintaining the substrate within the processing chamber at a temperature of about −40 degrees Celsius to about 100 degrees Celsius (e.g., about 0 degrees Celsius to about 50 degrees Celsius or about −10 degrees Celsius to about 80 degrees Celsius). The chamber pressure may range from about 1 mTorr to about 2 Torr (e.g., about 1 mTorr to about 1 Torr; or about 1 Torr to about 2 Torr). An RF power of about 100 W to about 2,000 W, e.g., about 100 W to about 1,800 W, about 500 W to about 1,500 W, or about 800 W to about 1,000 W, supplied by one or more RF sources (e.g., first RF power source 170 and second RF power source 171 or a single RF power source) may be utilized for ionization of the first hardmask gas. In one or more embodiments, the formed first hardmask includes a thickness of about 1 nm to about 20 nm, such as about 5 nm to about 15 nm, such as about 10 nm.

At operation 320, a second hardmask gas is provided into the processing region of a process chamber. In one or more embodiments, the first processing gas is provided at a flow rate of about 400 sccm to about 2400 sccm, such as about 500 sccm to about 2000 sccm. The second hardmask gas may include at least one silicon containing source. In one example, the second hardmask gas facilitates deposition of a silicon film, such as silicon oxide, silicon oxynitride, silicon nitride, or silicon. The silicon containing source can include one or more of, silane, disilane, tetrasilane, trisilane, tri silylamine, alkyl silane, any derivatives thereof, and/or any isomers thereof. The second hardmask gas may further include an inert gas, a dilution gas, oxygen, a nitrogen-containing gas, or combinations thereof. The silicon containing source can be any liquid or gas.

At operation, 325, a second hardmask is formed by exposing the substrate to the second hardmask gas, while maintaining the substrate within the processing chamber at a temperature of about −40 degrees Celsius and about 100 degrees Celsius (e.g., about 0 degrees Celsius to about 50 degrees Celsius or about −10 degrees Celsius to about 80 degrees Celsius). The chamber pressure may range from about 1 mTorr to about 2 Torr (e.g., about 1 mTorr and about 1 Torr; or about 1 Torr and about 2 Torr). An RF power of about 100 W to about 1,000 W, e.g., about 100 W to about 800 W, about 400 W to about 700 W, or about 500 W to about 600 W, supplied by one or more RF sources (e.g., first RF power source 170 and second RF power source 171) may be utilized. The RF power supplied by the one or more RF sources includes an RF frequency. In one or more embodiments, the RF frequency of the RF power supplied by the first RF source is within range of about 11 MHz to about 15 MHz range, such as about 13 MHz to about 14 MHz, such as about 13.5 MHz. In one or more embodiments, the RF frequency of the RF power supplied by the second RF source is within a range of about 1.8 MHz to about 2.2 MHz, such as about 1.95 MHz to about 2.05 MHz, such as about 2 MHz. In one or more embodiments, operation 325 includes a deposition time of about 60 seconds (s) to about 120 s. In one or more embodiments, the formed second hardmask includes a thickness of about 20 nm to about 40 nm, such as about 25 nm to about 30 nm, such as about 27 nm.

At operation 330, an underlayer gas is provided into the processing region of the process chamber. The underlayer gas may include at least one hydrocarbon source and/or carbon-containing source. The underlayer gas may further optionally include an inert gas, a dilution gas, a nitrogen-containing gas, or combinations thereof. In one example, the precursor is vapor at room temperature, which simplifies the hardware for material metering, control and delivery to the chamber. In other examples, the precursor may not be a vapor at room temperature and is dependent on composition of the precursor.

In one embodiment, the hydrocarbon compound has a general formula CxHy, where x has a range of about 1 and 20 and y has a range of about 1 and 20. In one implementation, the hydrocarbon compound is an alkane. In other embodiments, the precursor gas mixture comprises CₓH_{y}N_{z}, TMS, B₂H₆, SiH₄ and WF_{E} or combinations thereof.

Suitable dilution, treatment, and/or inert gases (e.g., helium (He), argon (Ar), xenon, nitrogen (N₂), N₂O, oxygen (O₂), SiF₄, NF₃, B₂H₆, and SiH₄ or combinations thereof, among others) may be added to the gas mixture. Alternatively, dilution gases may not be used during the deposition.

At operation 340, in the underlay gas is ionized into a plasma in the processing region to deposit an underlay, such as an underlayer, for example the resist underlayer 204. In some embodiments, deposition of the underlay may be performed by utilizing pulsed plasma, such as a pulsed radio frequency (RF) plasma. Without being bound by theory, pulsed plasma can change an ion to radical ratio in the plasma thus modifying film properties. In some embodiments, the pulsed RF plasma techniques includes a single pulsed RF source. In such an example, the RF power may be a single frequency power, or a dual-frequency RF power that has a high frequency component and a low frequency component. The RF power maybe all high-frequency RF power, for example at a frequency of about 13.56 MHz, applied at a power level of about 5 W to about 3000 W. To pulse the bias power, the radio frequency power is switched on and off during the deposition process. The bias power frequency and the pulsing frequency may be adjusted depending on the substrate material being processed. In some embodiments, depositing an underlayer, such as underlayer 204 on the second hardmask, e.g., the silicon hardmask 206, includes depositing the resist underlayer 204 such that a rapid transition between the silicon hardmask 206 and the resist underlayer 204 occurs to form distinct layers between the silicon hardmask 206 and the resist underlayer 204. In some embodiments, the resist underlayer 204 formed comprises a thickness of about 10 Å and about 50 Å.

In the embodiments described herein, during deposition of the resist underlayer, the substrate may be maintained at a temperature of about −40 degrees Celsius and about 100 degrees Celsius (e.g., about 0 degrees Celsius to about 50 degrees Celsius or about −10 degrees Celsius to about 80 degrees Celsius). The chamber pressure may range from about 1 mTorr to about 2 Torr (e.g., about 1 mTorr and about 1 Torr; or about 1 Torr and about 2 Torr).

In an embodiment, forming the resist underlayer 204 utilizing a pulsed RF plasma technique within the same processing volume used to provide the first hardmask and/or the second hardmask enables control over the porosity of the resist underlayer 204 such that the formation of pinholes in the resist underlayer 204 is minimized to improve the density of the resist underlayer 204. Without being bound by theory, transferring the substrate between various processing volumes between providing the first hardmask and/or second hardmask may cause the formation of pinholes may be due to exposing the resist underlayer 204 to air. By controlling the porosity of the resist underlayer 204, the effect of the second hardmask disposed below the resist underlayer 204 can be minimized. As a result, the resist underlayer 204 exhibits improved adhesion to the silicon hardmask 206.

Subsequent to operation 340, an EUV photoresist 202 is formed on the resist underlayer 204. In one or more embodiments, the EUV photoresist 202 is formed on the resist underlayer 204 in a different processing volume and/or chamber than was used in one or more of the operations 310, 315, 325, and 330. In various embodiments, the EUV photoresist 202 may be formed directly on the resist underlayer 204 without an intervening surface layer. In some embodiments, the EUV photoresist 202 is deposited on the resist underlayer 204 using one or more of the EUV photoresist deposition techniques (e.g., a spin coating). The EUV photoresist 202 may be a polymer material sensitive to a certain wavelength of electromagnetic radiation, and may be deposited through a spin coating process, CVD process, PECVD process, and the like.

In some embodiments, the EUV photoresist 202 is a carbon-based polymer sensitive to ultraviolet light (e.g., CAR photoresist), such as a phenolic resin, an epoxy resin, or an azo napthenic resin. In other embodiments, the EUV photoresist 202 may be a metal oxide photoresist. The EUV photoresist 202 may be a positive or a negative photoresist. Preferred positive photoresists may be selected from the group consisting of a 248 nm photoresist, a 193 nm photoresist, a 157 nm photoresist, and a phenolic resin matrix with a diazonapthoquinone sensitizer. Preferred negative photoresists may be selected from the group consisting of poly-cis-isoprene and poly-vinylcinnamate.

In some embodiments, after the EUV photoresist 202 is formed on the resist underlayer 204, the EUV photoresist 202 may be patterned and etched to from a plurality of features. In some embodiments, the plurality of features comprises line and space structures. In other embodiments, the plurality of features comprises pillar structures.

Without being bound by theory, by providing the first hardmask, second hardmask, and EUV underlayer to the substrate in the same processing chamber, a reduction in the stack roughness may occur, thereby positively impacting line width roughness and concurrently increasing adhesion between the first hardmask, second hardmask, resist underlayer, and EUV resist.

The film stack and method described herein have the benefit of improving surface adhesion between the various layers thus stabilizing the photoresist during etching to improve LER. Additionally, the film stack and methods herein may increase interface control without a queue time effect by utilizing a single processing volume for the deposition of the carbon hardmask, silicon hardmask, and resist underlayer. Furthermore, the film stack and method described herein have the benefit of reducing surface roughness of the filmstack and/or each layer of the filmstack improving line width roughness.

While the foregoing is directed to embodiments of the present disclosure, other and further embodiments of the disclosure may be devised without departing from the basic scope thereof, and the scope thereof is determined by the claims that follow.

What is claimed is:

1. A method of processing a substrate, comprising:
introducing a first hardmask gas to a processing volume of a processing chamber to form an amorphous carbon hardmask film on a substrate disposed in the processing volume, the first hardmask gas comprising a carbon containing gas;
introducing a second hardmask gas to the processing volume to form a silicon hardmask film on the amorphous carbon hardmask film, the second hardmask gas comprising a silicon containing gas; and
introducing an underlayer gas mixture to the processing volume to deposit a resist underlayer on the silicon hardmask film.

2. The method of claim 1, further comprising disposing an extreme ultraviolet (EUV) photoresist on the resist underlayer in the processing volume.

3. The method of claim 1, wherein forming the amorphous carbon hardmask film comprises exposing the substrate to ions of one or more plasmas and supplying simultaneously a radio frequency power of about 500 W to about 3000 W when exposing the substrate to ions of one or more plasmas.

4. The method of claim 1, wherein forming the silicon hardmask film comprises exposing the amorphous carbon hardmask film to ions of one or more plasma and supplying a radio frequency power of about 500 W to about 3000 W while exposing the amorphous carbon hardmask film to ions of one or more plasmas.

5. The method of claim 1, wherein introducing the underlayer gas mixture comprises exposing the silicon hardmask film to ions of one or more plasmas and supplying a radio frequency power of about 500 W to about 3000 W while exposing the silicon hardmask film to ions of one or more plasmas.

6. The method of claim 1, wherein introducing the first hardmask gas and the second hardmask gas to the processing volume is performed at a pressure of about 100 mTorr to about 400 mTorr.

7. The method of claim 1, wherein introducing the first hardmask gas and the second hardmask gas to the processing volume is performed at a temperature of about −40° C. to about 100° C.

8. The method of claim 1, wherein the first hardmask gas comprises at least one of acetylene, propylene, or ethylene.

9. The method of claim 1, wherein the second hardmask gas comprises at least one of silane, disilane, tetrasilane, trisilane, tri silylamine, or alkyl silane.

10. The method of claim 1, wherein the underlayer gas mixture comprises at least one of acetylene, propylene, ethylene, silane, disilane, tetrasilane, trisilane, tri silylamine, alkyl silane, diborane, or alkyl boranes.

11. A non-transitory computer readable medium comprising instructions that, when executed by at least one processor of at least a substrate processing system, cause the at least one processor to perform operations comprising:
introducing a first hardmask gas to a processing volume of a processing chamber to form an amorphous carbon hardmask film on a substrate disposed in the processing volume, the first hardmask gas comprising a carbon containing gas;
introducing a second hardmask gas to the processing volume to form a silicon hardmask film on the amorphous carbon hardmask film, the second hardmask gas comprising a silicon containing gas; and
providing an underlayer gas mixture to the processing volume to deposit a resist underlayer on the silicon hardmask film in the processing volume.

12. The non-transitory computer readable medium of claim 11, wherein the processor further performs the operation of forming an EUV photoresist on the resist underlayer in the processing volume.

13. The non-transitory computer readable medium of claim 11, wherein the first hardmask gas comprises at least one of acetylene, propylene, or ethylene.

14. The non-transitory computer readable medium of claim 11, wherein the second hardmask gas comprises at least one of silane, disilane, tetrasilane, trisilane, tri silylamine, or alkyl silane.

15. The non-transitory computer readable medium of claim 11, wherein the underlayer gas mixture comprise at least one of acetylene, propylene, ethylene, silane, disilane, tetrasilane, trisilane, tri silylamine, alkyl silane, diborane, or alkyl boranes.

16. A substrate processing system, comprising:
a processing chamber comprising a processing volume;
one or more hardmask gas sources;
one or more underlayer gas sources;
a substrate support disposed in the processing volume;
one or more bias electrodes disposed at least partially in the substrate support;
a radiofrequency (RF) source electrically coupled to the one or more bias electrodes;
at least one processor; and
one or more memories coupled to the at least one processor and storing instructions that, when executed by the at least a processor, cause the at least one processor to perform operations comprising:
introducing a first hardmask gas to the processing volume of the processing chamber to form an amorphous carbon hardmask film on a substrate disposed in the processing volume, the first hardmask gas comprising a carbon containing gas;
introducing a second hardmask gas to the processing volume to form a silicon hardmask film on the amorphous carbon hardmask film, the second hardmask gas comprising a silicon containing gas; and
providing an underlayer gas mixture to the processing volume to deposit a resist underlayer on the silicon hardmask film in the processing volume.

17. The substrate processing system of claim 16, wherein the processor further performs the operation of forming an EUV photoresist on the resist underlayer in the processing volume.

18. The substrate processing system of claim 16, wherein the first hardmask gas comprises at least one of acetylene, propylene, or ethylene.

19. The substrate processing system of claim 16, wherein the second hardmask gas comprises at least one of silicon oxide, silicon oxynitride, silicon nitride, silicon, silane, disilane, tetrasilane, trisilane, tri silylamine, or alkyl silane.

20. The substrate processing system of claim 16, wherein the underlayer gas mixture comprises at least one of acetylene, propylene, ethylene, silane, disilane, tetrasilane, trisilane, tri silylamine, alkyl silane, diborane, or alkyl boranes.
